(19) United States
(12) Patent Application Publication
(10) Pub. No.: US 2025/0216795 A1
(43) Pub. Date: Jul. 3, 2025

(54) METHOD OF USING LITHOGRAPHY APPARATUS

(71) Applicant: SAMSUNG ELECTRONICS CO., LTD., Suwon-si (KR)

(72) Inventors: Ahyun Park, Suwon-si (KR); Kwangseok Maeng, Suwon-si (KR); Soojung Kim, Suwon-si (KR); Insung Kim, Suwon-si (KR); Jae-Hyoung Kim, Suwon-si (KR); Hoyoung Lee, Suwon-si (KR); Hyungrok Jang, Suwon-si (KR); Noyoung Chung, Suwon-si (KR); Hyunjae Cho, Suwon-si (KR)

(73) Assignee: SAMSUNG ELECTRONICS CO., LTD., Suwon-si (KR)

(21) Appl. No.: 18/955,224

(22) Filed: Nov. 21, 2024

(30) Foreign Application Priority Data
Dec. 27, 2023 (KR) 10-2023-0193579
Apr. 18, 2024 (KR) 10-2024-0052195

(51) Int. Cl. G03F 7/00

(52) U.S. Cl. CPC G03F 7/70258; G03F 7/7025; G03F 7/70308; G03F 7/70508

(57) ABSTRACT

A lithography method may include placing a patterning device and a substrate in a lithography apparatus, irradiating a first region of the substrate with a diffraction light and increasing an optical path difference (OPD) of the diffraction light on the first region. The diffraction light may include first and second diffraction lights, and the OPD may be a difference in optical path between the first and second diffraction lights. The lithography apparatus may include an illumination source part configured to emit a radiation beam that is used as the diffraction light, a substrate table supporting the substrate, a supporting structure supporting the patterning device and optically connected to the illumination source part, and a projection part optically connected to the supporting structure and configured to irradiate the substrate with the first and second diffraction lights. The illumination source part may include a monopole source.

### CROSS-REFERENCE TO RELATED APPLICATIONS

This U.S. non-provisional patent application claims priority under 35 U.S.C. § 119 to Korean Patent Application Nos. 10-2023-0193579 and 10-2024-0052195, filed on Dec. 27, 2023 and Apr. 18, 2024, respectively, in the Korean Intellectual Property Office, the entire contents of which are hereby incorporated by reference.

### BACKGROUND

### 1. Field

Embodiments of the present disclosure relate to a method of using a lithography apparatus, and in particular, to a method of measuring a pattern shift amount on a substrate to determine a defocusing amount in a lithography process.

### 2. Brief Description of Related Art

A semiconductor device is fabricated through several processes. A lithography process may include an exposing step. A circuit pattern may be formed on a substrate by performing the exposing step in a lithography apparatus. The lithography apparatus is used to copy a pattern, which is designed in a patterning device, to a photoresist layer on the substrate. For example, the exposing step in the lithography apparatus may include coating the substrate with the photoresist layer and exposing the photoresist layer to light passing through the patterning device. The light, which passes through the patterning device and a lens, may cause a chemical reaction of the photoresist layer coated on the substrate.

### SUMMARY

An embodiment of the present disclosure provides a method of increasing a difference in an optical path between a first diffraction light and a second diffraction light, in a lithography process.

An embodiment of the present disclosure provides a method of increasing a pattern shift amount of a pattern formed on a substrate, in a lithography process.

An embodiment of the present disclosure provides a method of increasing a pattern shift amount, which is caused by a change in a focal length of a diffraction light, in a lithography process.

An embodiment of the present disclosure provides a method of measuring a pattern shift amount on a substrate to determine a defocusing amount of a diffraction light, in a lithography process.

According to embodiments of the present disclosure, a method of using a lithography apparatus is provided and includes: placing a patterning device and a substrate in the lithography apparatus; irradiating, by the lithography apparatus, a first region of the substrate with a diffraction light; and increasing an optical path difference (OPD) of the diffraction light on the first region, wherein the diffraction light includes a first diffraction light and a second diffraction light, wherein the OPD is a difference in an optical path of the first diffraction light and an optical path of the second diffraction light, wherein the lithography apparatus includes: an illumination source configured to emit a light beam that is used as the diffraction light; a substrate table supporting the substrate; a supporting structure that supports the patterning device and is optically connected to the illumination source; and a projection part that is optically connected to the supporting structure and is configured to irradiate the substrate with the first diffraction light and the second diffraction light, and wherein the illumination source includes a monopole source (MPS).

According to embodiments of the present disclosure, a method of using a lithography apparatus may be provided and include: placing a patterning device and a substrate in the lithography apparatus; irradiating, by the lithography apparatus, the substrate with a diffraction light; and increasing a pattern shift amount on the substrate, wherein the diffraction light includes a first diffraction light and a second diffraction light, wherein the lithography apparatus includes: an illumination source configured to emit a light beam to be used as the diffraction light; a substrate table supporting the substrate; a supporting structure supporting the patterning device and optically connected to the illumination source; and a projection part optically connected to the supporting structure and configured to irradiate the substrate with the diffraction light, wherein the projection part includes an aperture that is configured to control a profile of the diffraction light, wherein the illumination source includes a monopole source (MPS), and wherein the increasing the pattern shift amount on the substrate includes changing an optical path of the first diffraction light.

According to embodiments of the present disclosure, a method of using a lithography apparatus may be provided and include: placing a patterning device and a substrate in the lithography apparatus; irradiating, by the lithography apparatus, the substrate with a light beam; causing a pattern shift on the substrate; and increasing an amount of the pattern shift, wherein the lithography apparatus includes: an illumination source configured to emit the light beam; an illuminator optically connected to the illumination source and configured to control the light beam; a substrate table supporting the substrate; a supporting structure supporting the patterning device; and a projection part optically connected to the supporting structure and configured to irradiate the substrate with diffraction light, and wherein the illumination source includes a monopole source (MPS).

### BRIEF DESCRIPTION OF DRAWINGS

FIG. 1 is a schematic diagram illustrating a lithography apparatus according to an embodiment of the present disclosure.

FIG. 2 is a schematic diagram illustrating a lithography apparatus according to an embodiment of the present disclosure.

FIG. 3 is a flow chart illustrating a method of using a lithography apparatus according to an embodiment of the present disclosure.

FIG. 4A is a schematic diagram illustrating a first pupil plane of a dipole mode according to an embodiment of the present disclosure.

FIG. 4B is a schematic diagram illustrating a first pupil plane of a monopole mode according to an embodiment of the present disclosure.

FIG. 4C is a schematic diagram illustrating a first pupil plane of a monopole mode according to an embodiment of the present disclosure.

FIG. 5A is a schematic diagram illustrating a first diffraction light and a second diffraction light passing through a second pupil plane according to an embodiment of the present disclosure.

FIG. 5B is a schematic diagram illustrating a first diffraction light and a second diffraction light passing through a second pupil plane according to an embodiment of the present disclosure.

FIG. 5C is a schematic diagram illustrating a first diffraction light and a second diffraction light passing through a second pupil plane according to an embodiment of the present disclosure.

FIG. 6 is a graph showing a pattern shift amount on a substrate that is caused by a change in a focal length of a diffraction light, according to an embodiment of the present disclosure.

FIG. 7 is a schematic diagram illustrating a defocusing amount on a substrate according to an embodiment of the present disclosure.

FIG. 8 is a flow chart illustrating a method of using a lithography apparatus according to an embodiment of the present disclosure.

FIG. 9 is a flow chart illustrating a method of using a lithography apparatus according to an embodiment of the present disclosure.

### DETAILED DESCRIPTION

Non-limiting example embodiments of the present disclosures will now be described more fully with reference to the accompanying drawings, in which example embodiments are shown. Like reference numerals in the drawings denote like elements, and thus repeated descriptions thereof may be omitted.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

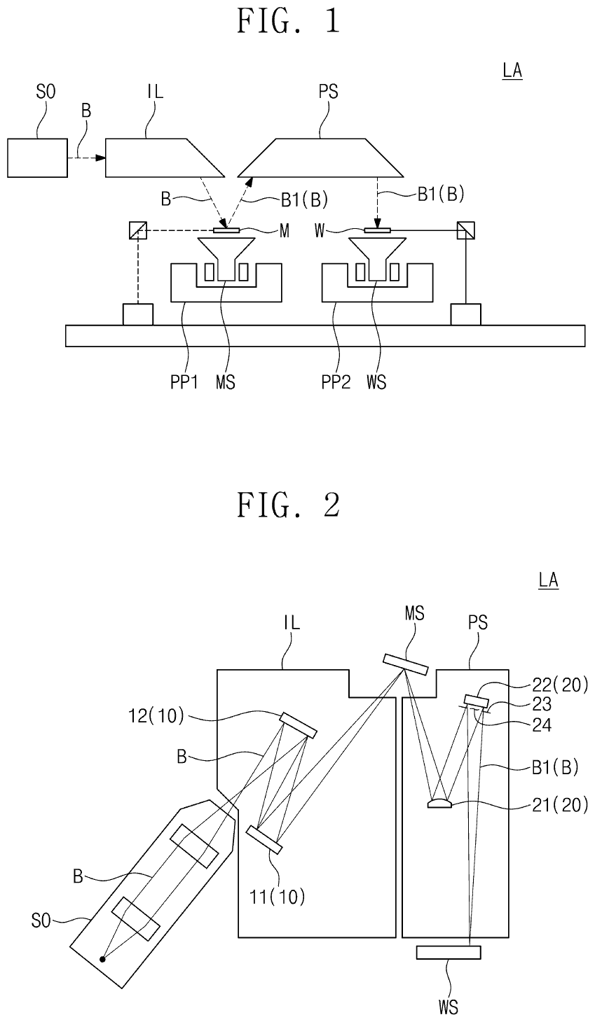

FIG. 1 is a schematic diagram illustrating a lithography apparatus LA according to an embodiment of the present disclosure, and FIG. 2 is a schematic diagram illustrating the lithography apparatus LA according to an embodiment of the present disclosure.

Referring to FIG. 1, the lithography apparatus LA may be provided. The lithography apparatus LA may include an illumination source part SO, an illuminator IL, a supporting structure MS, a substrate table WS, a first positioner PP1 (e.g., at least one actuator), a second positioner PP2 (e.g., at least one actuator), and a projection part PS. Example embodiments will be described in the present specification to include an extreme ultraviolet (EUV) lithography apparatus, which is used for a reflection-type exposure method, but the lithography apparatus LA is not limited to this example. The lithography apparatus LA may include a transmission-type lithography apparatus. A deep ultraviolet (DUV) light may be used for the transmission-type lithography apparatus. The transmission-type lithography apparatus may include a projection lens. The description that follows will refer to an example, in which a reflection-type lithography apparatus is used in a lithography process.

The illumination source part SO may be configured to emit light. The light may include a radioactive ray. In the following description, the light may be a lightbeam B. The light beam B may include a radiation beam. However, the type of the light beam B is not limited to this. The illumination source part SO may be optically connected to the illuminator IL. The illumination source part SO may be configured to irradiate the illuminator IL with the light beam B. The radioactive ray may include EUV light. In the illumination source part SO, an EUV beam may be generated by a discharge-produced plasma (DPP) method or a laser-produced plasma (LPP) method. The LPP method may include generating plasma from a source material capable of emitting light within an EUV wavelength range. The source material may include an element capable of emitting light of a desired wavelength or exhibiting a desired line spectrum and may be provided in the form of droplets, streams, or clusters. The element may include one from among gadolinium (Gd), xenon (Xe), lithium (Li), and tin (Sn). However, the element for the source material is not limited to these materials. The illumination source part SO may be configured to provide a laser beam causing the excitation of the source material. The plasma may emit a radioactive ray with an EUV wavelength, and the EUV beam may be generated by collecting the radioactive ray using a beam collector, which is provided in the illumination source part SO. However, the method of generating the EUV beam is not limited to this example. The illumination source part SO may further include various types of optical elements (e.g., refractive, reflective, magnetic, electromagnetic, or electrostatic components), which are used to control the light beam B.

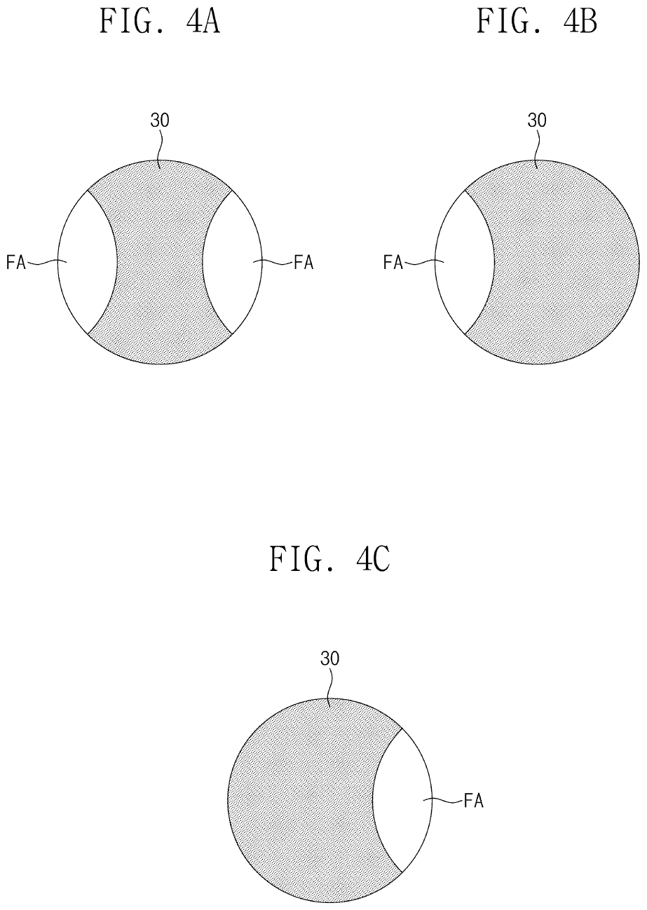

The illuminator IL may receive the light beam B from the illumination source part SO. The illuminator IL may control the light beam B. The illuminator IL may include a pupil unit. In the pupil unit, the distribution and uniformity in the intensity of the light beam B may be controlled depending on an angle of the light beam B. The pupil unit may have a first pupil plane 30 (e.g., see FIG. 4). The intensity distribution of the light beam B on the first pupil plane 30 may be adjusted in an outward or inward radial direction. In the illuminator IL, the light beam B may be controlled to achieve the desired uniformity and distribution in the intensity of the light beam B, on a cross-section of the light beam B. The illuminator IL may be configured to produce various beam intensity distributions on the first pupil plane 30. If the light beam B passes through a center axis of the first pupil plane 30, it may be said that the light beam B is in an on-axis mode. If the light beam B does not pass through the center axis of the first pupil plane 30, it may be said that the light beam B is in an off-axis mode.

The supporting structure MS may be configured to support a patterning device M. In the supporting structure MS, mechanical, vacuum, electrostatic, or clamping techniques (and corresponding structures) may be used to support the patterning device M. However, the method of supporting the patterning device M using the supporting structure MS is not limited to this example. The supporting structure MS may be optically coupled to the illumination source part SO. The light beam B, which is emitted from the illumination source part SO, may be incident on the supporting structure MS via the illuminator IL. The patterning device M may include a pattern, which will be printed on a substrate W. The patterning device M may include a plurality of patterns. However, the pattern of the patterning device M may be different in size and shape from the pattern, which will be printed on the substrate W. The light beam B, which is incident into the patterning device M, may be patterned by the pattern of the patterning device M. For example, the light beam B may be diffracted by the patterning device M. In the present specification, a patterned light beam B1 may refer to the light beam B that passed through the patterning device M. In the present specification, the patterned light beam B1 may be referred to as a diffraction light. The supporting structure MS may be supported by the first positioner PP1. The first positioner PP1 may be configured to move the supporting structure MS. The first positioner PP1 may be controlled to place the supporting structure MS on a propagation path of the light beam B.

In the present specification, the patterning device M should be understood to refer to any device, which can be used to form a desired image on the substrate W or a target layer on the substrate W. The image should be understood as an abstract or physical structure defined by patterns and voids therebetween. The term “pattern,” which is given in the expression “patterned light beam,” may be used to represent a spatial variation in optical property (e.g., intensity or phase) of the light beam that is defined by a specific function layer in the patterning device M. The patterning device M may be of a transmission-type or a reflection-type. The patterning device M may include a mask, a programmable mirror array, and a programmable liquid crystal display (LCD) panel. The mask may include a binary mask, a phase-shift mask, and a hybrid mask. However, the kind of the mask is not limited to this example.

The projection part PS may be optically connected to the supporting structure MS. The light beam B1, which is reflected and/or diffracted by the patterning device M, may pass through the projection part PS. An inner space of the projection part PS may be maintained to a vacuum state. However, embodiments of the present disclosure are not limited to this example. The projection part PS may include a vacuum pump, which is used to maintain the inner space to a high vacuum state. The projection part PS may be configured to concentrate the patterned light beam B1 onto the substrate W. The concentration of the patterned light beam B1 achieved by the projection part PS may make it possible to increase the resolution of the pattern, which will be printed on the substrate W.

The substrate table WS may support the substrate W. In the present specification, the substrate W may be a silicon substrate, but embodiments of the present disclosure are not limited to this example. The substrate W may include a first region. The first region may be an arbitrarily-chosen region of the substrate W. The substrate table WS may be supported by the second positioner PP2. The second positioner PP2 may be configured to move the substrate table WS and the position of the substrate W may be changed through this process. The second positioner PP2 may be used to place the substrate W on the path of the light beam B.

In an embodiment, the lithography apparatus LA according to an embodiment of the present disclosure may have a structure schematically illustrated in FIG. 2. In FIG. 2, the lithography apparatus LA is illustrated to have a physical configuration different from the configuration shown in FIG. 1, but there is no difference in operation mechanism. The lithography apparatus LA may include the illumination source part SO, the illuminator IL, the supporting structure MS, the projection part PS, and the substrate table WS. The illumination source part SO, the illuminator IL, the supporting structure MS, the projection part PS, and the substrate table WS may be provided to have substantially the same function and structure as described above.

The illuminator IL may include a vertical-incident reflector 10. The vertical-incident reflector 10 may include a first reflector 11 and a second reflector 12. The light beam B, which is emitted from the illumination source part SO, may be incident on the supporting structure MS (or the patterning device M thereon) by the vertical-incident reflector 10 in the illuminator IL. The light beam B may be reflected by the patterning device M, which is placed on the supporting structure MS. The light beam B may be patterned by the patterning device M.

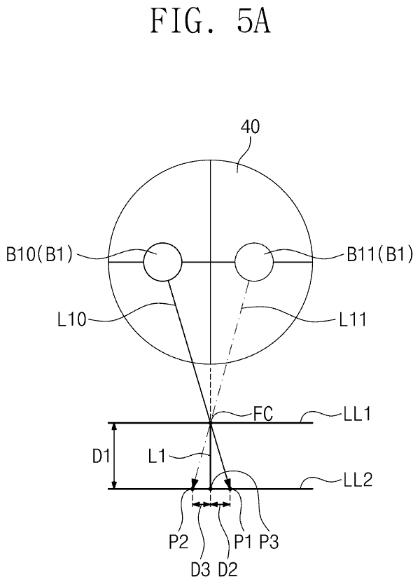

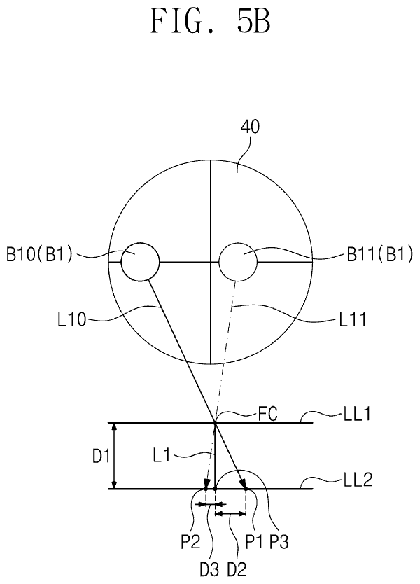

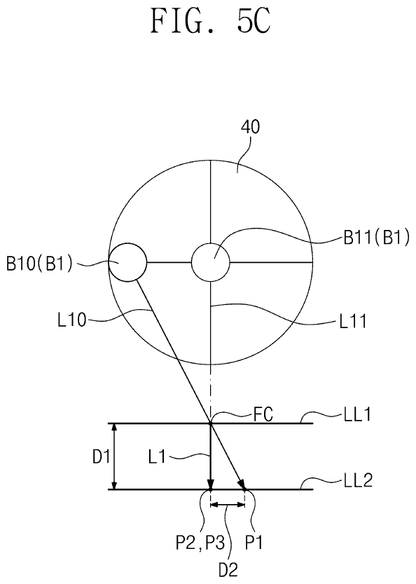

The patterned light beam B1 may be incident on the substrate table WS (or a substrate W thereon) through the projection part PS. The projection part PS may include a reflecting element 20. The reflecting element 20 may include a first reflecting element 21 and a second reflecting element 22. The patterned light beam B1 may be used to perform an imaging process on the substrate table WS, on which the substrate W is loaded. The projection part PS may include a NA disk 23, which is provided to face a front surface of the reflecting element 20 and is pierced by an aperture 24. The size of the aperture 24 may be used to adjust an incidence angle of the patterned light beam B1 propagating toward the substrate table WS. The aperture 24 may be used to control a profile of the light beam B. The projection part PS may have a second pupil plane 40 (e.g., see FIGS. 5A-C) that is defined by the reflecting element 20 in the projection part PS.

The lithography apparatus LA may further include a control unit (e.g., a controller). The control unit may be used to control the substrate table WS and the supporting structure MS. The positions of the substrate W and the patterning device M may be examined and controlled by the control unit. The control unit may also be used to gather data. The data may contain information on a pattern shift amount on the substrate W, which is caused by a change in a focal length of the diffraction light (e.g., the patterned light beam B1). However, the data is not limited to this example.

According to embodiments of the present disclosure, the control unit (e.g., the controller) may include at least one processor and memory storing computer instructions. The computer instructions may be configured to, when executed by the at least one processor, cause the control unit to perform its functions.

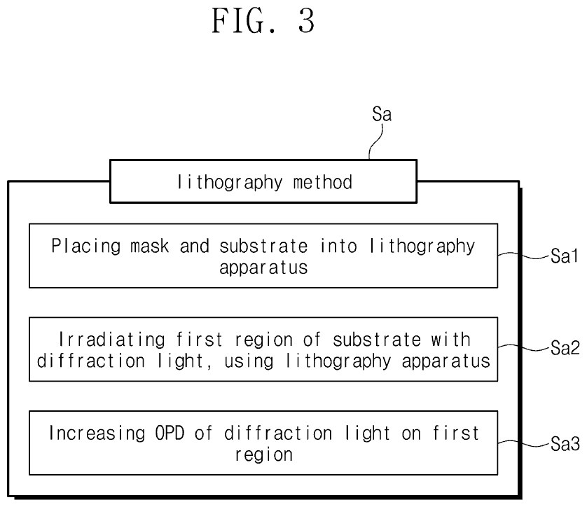

FIG. 3 is a flow chart illustrating a method of using a lithography apparatus Sa, according to an embodiment of the present disclosure.

Referring to FIG. 3, the method of using the lithography apparatus Sa may include placing the patterning device M (e.g., a mask) and the substrate W into the lithography apparatus LA (operation Sal), irradiating the first region of the substrate W with the diffraction light (e.g., the patterned light beam B1) using the lithography apparatus LA (operation Sa2), and increasing an optical path difference (OPD) of the diffraction light (e.g., the patterned light beam B1) on the first region (operation Sa3).

The diffraction light (e.g., the patterned light beam B1) may include a first diffraction light B10 (e.g., see FIGS. 5A-C) and a second diffraction light B11 (e.g., see FIGS. 5A-C). The first diffraction light B10 may mean a zeroth-order diffraction light. The first diffraction light B10 may have the same propagation direction as a propagation direction of the light beam B that is not diffracted by the patterning device M. The first diffraction light B10 may not contain any image information on the patterning device M. The first diffraction light B10 may not contain information on a pattern of the patterning device M.

The second diffraction light B11 may mean a first-order diffraction light. The second diffraction light B11 may contain image information on the patterning device M. The second diffraction light B11 may contain information on the pattern of the patterning device M. A point, at which the first diffraction light B10 and the second diffraction light B11 meet each other, will be referred to as a focal point FC (e.g., see FIGS. 5A-C). The optical path of the first diffraction light B10 will be referred to as a first optical path L10 (e.g., see FIGS. 5A-C). The optical path of the second diffraction light B11 will be referred to as a second optical path L11 (e.g., see FIGS. 5A-C). A difference in length between the first optical path L10 and the second optical path L11 will be referred to as an optical path difference (OPD). If the focal point FC is formed at a desired position, no pattern-shifting phenomenon may occur. However, if the focal point FC is not formed on the substrate W or at a desired position on the substrate W, a pattern-shifting phenomenon may occur.

FIG. 4A is a schematic diagram illustrating the first pupil plane 30 of a dipole mode according to an embodiment of the present disclosure. FIG. 4B is a schematic diagram illustrating the first pupil plane 30 of a monopole mode according to an embodiment of the present disclosure. FIG. 4C is a schematic diagram illustrating the first pupil plane 30 of a monopole mode according to an embodiment of the present disclosure. FIG. 5A is a schematic diagram illustrating the first diffraction light B10 and the second diffraction light B11 passing through the second pupil plane 40 according to an embodiment of the present disclosure. FIG. 5B is a schematic diagram illustrating the first diffraction light B10 and the second diffraction light B11 passing through the second pupil plane 40 according to an embodiment of the present disclosure. FIG. 5C is a schematic diagram illustrating the first diffraction light B10 and the second diffraction light B11 passing through the second pupil plane 40 according to an embodiment of the present disclosure.

The image of the patterning device M may be projected onto the substrate W in an off-axis mode, and here, the off-axis mode may include a dipole mode and a monopole mode. Referring to FIG. 4A, in the dipole mode, an intensity distribution of the light beam B may include two off-axis regions FA on the first pupil plane 30. The off-axis region FA may include a portion of an edge region of the first pupil plane 30. The two off-axis regions FA may be formed at opposite sides of the first pupil plane 30. The two off-axis regions FA may have a rotational symmetry with respect to the center of the first pupil plane 30. In the case where the off-axis mode is a dipole mode, the illumination source part SO may include a dipole source (DPS). FIGS. 4B and 4C illustrate two different examples of the monopole mode exhibiting pupil rotational asymmetry on the first pupil plane 30. In the monopole mode, the light beam B may be concentrated on a single off-axis region FA of the first pupil plane 30. In the monopole mode, the cross-section of the light beam B may have various shapes. For example, the cross-section of the light beam B may have a circular shape, but in an embodiment, it may have one from among square, leaf, and line shapes. The shape of the cross-section of the light beam B is not limited to these examples. FIG. 4B illustrates an example of a left monopole mode. FIG. 4C illustrates an example of a right monopole mode. In the case where the off-axis mode is the monopole mode, the illumination source part SO may include a monopole source (MPS). When the intensity distribution of the light beam B on the first pupil plane 30 has the rotational asymmetry, a position of at least a portion of a pattern, which is printed on the substrate W, may vary depending on a focal point of the light beam B in the lithography apparatus LA.

FIGS. 5A, 5B, and 5C illustrate the first diffraction light B10 and the second diffraction light B11 on the second pupil plane 40. In FIGS. 5A, 5B, and 5C, each of the first diffraction light B10 and the second diffraction light B11 on the second pupil plane 40 are illustrated to have a circular cross-section, for convenience in illustration. The first diffraction light B10 and the second diffraction light B11 may meet each other at a focal point on a focused region LL1. The focal point FC, at which the first diffraction light B10 and the second diffraction light B11 meet each other, may be located on the focused region LL1. The substrate W, on which the patterns will be printed, may be located on a defocused region LL2. The first diffraction light B10 may meet the defocused region LL2 at a first defocus point P1. The second diffraction light B11 may meet the defocused region LL2 at a second defocus point P2. The focused region LL1 and the defocused region LL2 may be spaced apart from each other by a first distance D1. The focused region LL1 and the defocused region LL2 may meet an imaginary first straight line L1. A length of the first straight line L1 may be equal to the first distance D1. The first straight line L1 may meet the focused region LL1 at the focal point FC. The first straight line L1 and the defocused region LL2 may meet each other at a third defocus point P3. A distance between the third defocus point P3 and the first defocus point P1 will be referred to as a second distance D2. A distance between the third defocus point P3 and the second defocus point P2 will be referred to as a third distance D3. A difference between the second distance D2 and the third distance D3 may be proportional to a pattern shift amount on the substrate W.

Referring to FIG. 5A, when the first diffraction light B10 and the second diffraction light B11 are symmetric to each other about the center of the second pupil plane 40, the second distance D2 may be equal to the third distance D3. In this case, no pattern-shifting phenomenon may occur. Referring to FIG. 5B, the first diffraction light B10 and the second diffraction light B11 may be asymmetric to each other about the center of the second pupil plane 40. The second distance D2 may be larger than the third distance D3. Since the second distance D2 is larger than the third distance D3, a pattern-shifting phenomenon may occur on the substrate W. The OPD in FIG. 5B may be increased to a value larger than the OPD in FIG. 5A. Referring to FIG. 5C, the first diffraction light B10 may be located in an edge region of the second pupil plane 40. The second diffraction light B11 may be located in a center region of the second pupil plane 40. Since the second defocus point P2 coincides with the third defocus point P3, the third distance may be zero. Here, the OPD may be maximized.

An optical path of the first diffraction light B10 may be controlled by the aperture 24 (e.g., see FIG. 2). The second optical path L11 may be controlled by the pattern of the patterning device M. The second optical path L11 may vary depending on a pattern pitch of the patterning device M. On the second pupil plane 40, the distance between the first diffraction light B10 and the second diffraction light B11 may be unchanged. Accordingly, by adjusting the aperture 24 of the lithography apparatus LA and the pattern pitch of the patterning device M, it may be possible to control the OPD. The pattern shift amount may be proportional to the OPD. In the case where the OPD is increased by the lithography apparatus LA, the pattern shift amount may be increased. By adjusting the aperture 24 and the pattern pitch of the patterning device M, it may be possible to control a pattern shift amount on the substrate W, which is caused by the defocusing of the diffraction light B1.

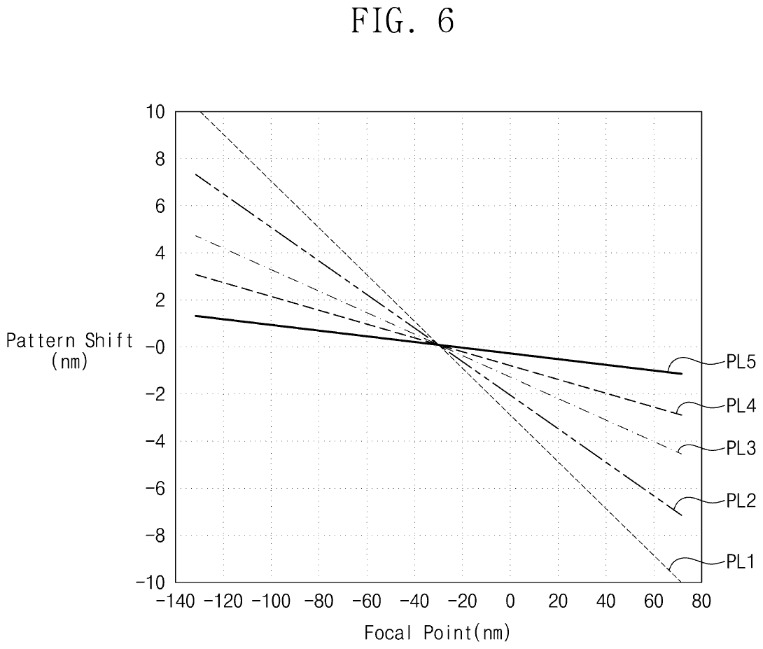

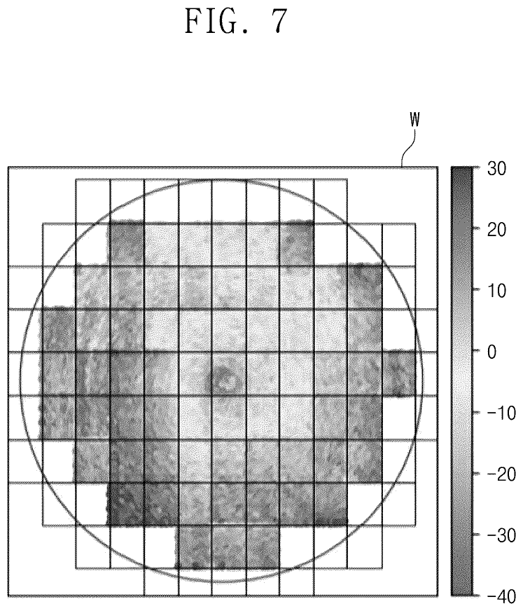

FIG. 6 is a graph showing a pattern shift amount on the substrate W, caused by a change in a focal length of the diffraction light B1 according to an embodiment of the present disclosure, and FIG. 7 is a schematic diagram illustrating a defocusing amount of the substrate W according to an embodiment of the present disclosure.

A first graph in FIG. 6 may be provided to show the relationship between defocusing and pattern shift, according to the pattern pitch of the patterning device M. The first graph may be measured and stored in the control unit. The 1a-th straight line PL1 shows a change in the pattern shift amount caused by the defocusing of the diffraction light B1 when the pattern of the patterning device M has a first pattern pitch. The 1b-th straight line PL2 shows a change in the pattern shift amount caused by the defocusing of the diffraction light B1 when the pattern of the patterning device M has a second pattern pitch. Similarly, the 1c-th straight line PL3, the 1d-th straight line PL4, and the 1e-th straight line PL5 show changes in the pattern shift amount caused by the defocusing of the diffraction light B1 when the pattern of the patterning device M has a third pattern pitch, a fourth pattern pitch, and a fifth pattern pitch, respectively. As shown in FIG. 6, the slope of the 1a-th straight line PL1 may be greater than the slope of the 1b-th straight line PL2, the slope of the 1c-th straight line PL3, the slope of the 1d-th straight line PL4, and the slope of the 1e-th straight line PL5. However, the changing of the pattern pitch of the patterning device M may not be the only method of increasing of the slope of the straight line in the first graph. The first optical path L10 may be changed by controlling the aperture 24, and this may make it possible to change the slope of the straight line in the first graph. The greater the change in the pattern shift amount caused by the defocusing, the easier it is to determine where defocusing occurred, in a step of measuring the pattern shift amount on the substrate W.

FIG. 7 shows an example of the pattern shift amount measured from the entire region of the substrate W. In the case where the pattern shift amount is measured from the entire region of the substrate W using the same condition as that in the measurement of the 1a-th straight line PL1 in FIG. 6, the 1a-th straight line PL1 may be used to find a defocusing position on the substrate W. For example, the substrate W may include a second region that is not overlapped with the first region. In the control unit, data obtained from the first region may be used to determine a defocusing amount on the second region. The determining of the defocusing amount may allow for real-time focus monitoring on the substrate W.

In the case where the substrate W with the shifted pattern is compared with the substrate W without any shifted pattern, the pattern shift amount caused by the defocusing may be increased. The substrate W with the shifted pattern may be the same as the substrate W without any shifted pattern. For example, the substrate W may include at least two regions, one of which has a shifted pattern, and the other of which does not have a shifted pattern. However, embodiments of the present disclosure are not limited to this example. The control unit may be used to obtain a 1-1 graph, which shows a defocusing-caused pattern shift amount measured using the substrate W with the shifted pattern. The control unit may be used to obtain a 1-2 graph, which shows a defocusing-caused pattern shift amount measured using the substrate W without a shifted pattern. The control unit may be used to obtain a second graph, in which a change in a defocusing-caused pattern shift amount is increased by merging the 1-1 graph and the 1-2 graph. This may make it possible to increase the sensitivity in the real-time focus monitoring on the substrate W.

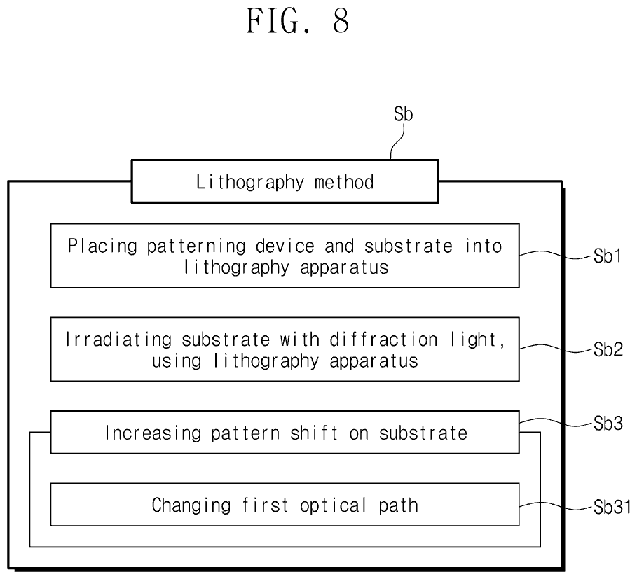

FIG. 8 is a flow chart illustrating a method of using a lithography apparatus Sb, according to an embodiment of the present disclosure.

Referring to FIG. 8, the method of using the lithography apparatus Sb (e.g., the lithography apparatus LA) may include placing the patterning device M and the substrate W into the lithography apparatus LA (operation Sb1), irradiating the substrate W with the diffraction light B1 using the lithography apparatus LA (operation Sb2), and increasing a pattern shift of the pattern on the substrate W (operation Sb3). The increasing of the pattern shift on the substrate W (operation Sb3) may include changing the first optical path L10.

The changing of the first optical path L10 may lead to a change of the position on the second pupil plane 40, through which the first diffraction light B10 passes. Since the first optical path L10 is changed, the OPD between the first diffraction light B10 and the second diffraction light B11 may be changed, and in this case, a pattern shift amount on the substrate W may be increased.

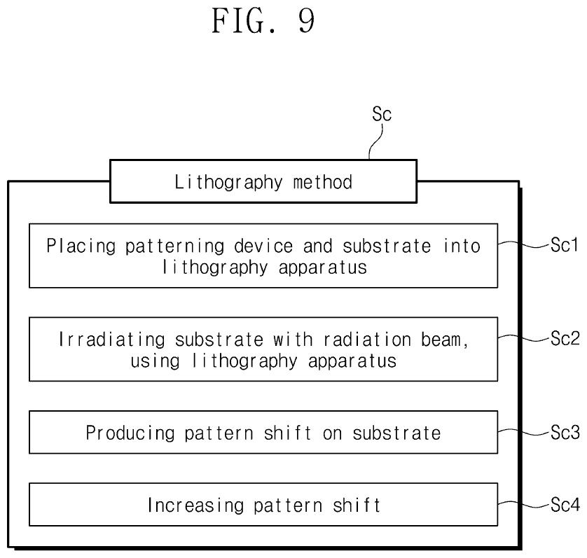

FIG. 9 is a flow chart illustrating a method of using a lithography apparatus Sc, according to an embodiment of the present disclosure.

Referring to FIG. 9, the method of using the lithography apparatus Sc (e.g., the lithography apparatus LA) may include placing the patterning device M and the substrate W in the lithography apparatus LA (operation Sc1), irradiating the substrate W with the light beam B using the lithography apparatus LA (operation Sc2), producing a pattern shift of the pattern on the substrate W (operation Sc3), and increasing the pattern shift (operation Sc4).

The producing of the pattern shift may be achieved by controlling the aperture 24 and the pattern pitch of the patterning device M. However, the method of producing the pattern shift is not limited to this example.

In a method of using a lithography apparatus according to an embodiment of the present disclosure, it may be possible to increase the defocusing-caused pattern shift on the substrate. The pattern shift may be increased by increasing the OPD. The pattern shift amount may be proportional to the OPD. The pattern shift may occur on the substrate when the lithography apparatus is operated in the monopole mode. The OPD may be adjusted by changing an optical path of the diffraction light. If the size and angle of the aperture are adjusted, the position of the first diffraction light on the second pupil plane may be changed. If the pattern pitch of the patterning device is adjusted, the position of the second diffraction light on the second pupil plane may be changed. In the case where there is a defocusing issue in the lithography apparatus caused by a change in the aperture and the pattern pitch of the patterning device, the control unit may determine the pattern shift amount on the substrate.

In a method of using a lithography apparatus according to an embodiment of the present disclosure, it may be possible to increase the sensitivity in finding a pattern shift on the substrate caused by a defocusing phenomenon and thereby to increase the sensitivity in the focus monitoring step. By controlling the aperture and the pattern pitch of the patterning device, it may be possible to obtain a graph, in which the pattern shift amount caused by the defocusing is maximally changed, as in the first graph of FIG. 6. In addition, graphs, which are respectively obtained from a substrate region with a shifted pattern and a substrate region without a shifted pattern, may be used to increase a change in the pattern shift amount, which is caused on the substrate by the defocusing. Thus, the sensitivity in the focus monitoring step may be improved.

In a method of using a lithography apparatus according to an embodiment of the present disclosure, it may be possible to realize the focus monitoring on the entire region of the substrate. Furthermore, in-chip or in-wafer focus monitoring may also become possible. On an arbitrary region of the substrate, it may be possible to obtain information on a pattern shift amount on the substrate, caused by the defocusing. For example, if a defocusing issue occurs on a first region of the substrate, the pattern shift amount on the first region may be measured. In the case where the defocusing-caused pattern shift on the first region is increased, the sensitivity in the focus monitoring step may be increased. If a pattern shift amount measured from a second region of the substrate is analyzed based on the data obtained from the first region, it may be possible to find the defocusing amount on the second region. If this method is applied to the entire region of the substrate, it may be possible to realize the in-chip or in-wafer focus monitoring, and this may make it possible to increase the efficiency in the semiconductor fabrication process.

In a method of using a lithography apparatus according to an embodiment of the present disclosure, it may be possible to increase a difference in an optical path between a first diffraction light and a second diffraction light.

In a method of using a lithography apparatus according to an embodiment of the present disclosure, it may be possible to increase a pattern shift amount of a pattern formed on a substrate.

In a method of using a lithography apparatus according to an embodiment of the present disclosure, it may be possible to increase a pattern shift amount caused by a change in a focal length of a diffraction light.

In a method of using a lithography apparatus according to an embodiment of the present disclosure, a defocusing amount of a diffraction light may be measured by measuring a pattern shift amount of a substrate.

According to embodiments of the present disclosure, the control unit (e.g., the controller) may control adjustment of the aperture 24 and/or the pattern pitch of the patterning device M such as to control the pattern shift amount. For example, the control unit may be configured to control at least one actuator that is configured to adjust the aperture 24 and/or the pattern pitch.

According to embodiments of the present disclosure, the control unit (e.g., the controller) may control the substrate table WS, and/or the supporting structure MS such as to control a position thereof. For example, the control unit may control the first positioner PP1 and/or the second positioner PP2.

According to embodiments of the present disclosure, the controller unit (e.g., the controller) may obtain data (e.g., data on the pattern shift) from at least one sensor, and may measure the pattern shift amount based on the data.

While non-limiting example embodiments of the present disclosure have been particularly shown and described, it will be understood by one of ordinary skill in the art that variations in form and detail may be made therein without departing from the spirit and scope of the present disclosure.

What is claimed is:

1. A method of using a lithography apparatus, comprising:
placing a patterning device and a substrate in the lithography apparatus;
irradiating, by the lithography apparatus, a first region of the substrate with a diffraction light; and
increasing an optical path difference (OPD) of the diffraction light on the first region,
wherein the diffraction light includes a first diffraction light and a second diffraction light,
wherein the OPD is a difference in an optical path of the first diffraction light and an optical path of the second diffraction light,
wherein the lithography apparatus includes:
an illumination source configured to emit a light beam that is used as the diffraction light;
a substrate table supporting the substrate;
a supporting structure that supports the patterning device and is optically connected to the illumination source; and
a projection part that is optically connected to the supporting structure and is configured to irradiate the substrate with the first diffraction light and the second diffraction light, and
wherein the illumination source includes a monopole source (MPS).

2. The method of claim 1, wherein the increasing the OPD of the diffraction light on the first region comprises increasing a pattern shift on the first region.

3. The method of claim 1, further comprising a controller configured to control movement of the substrate table and gather data.

4. The method of claim 3, further comprising obtaining, by the controller, a first graph showing a pattern shift amount on the first region of the substrate caused by a defocusing of the diffraction light.

5. The method of claim 4, wherein the obtaining the first graph comprises changing the optical path of the first diffraction light.

6. The method of claim 4, further comprising:
comparing, by the controller, data on the substrate without any pattern shift with data on the substrate with the pattern shift; and
obtaining, by the controller, a second graph showing a change in the pattern shift caused by a change in a focal length of the diffraction light,
wherein a slope of the second graph is greater than a slope of the first graph.

7. The method of claim 1, wherein the lithography apparatus is configured to execute an exposure operation through one from among reflection-type and transmission-type exposure methods.

8. The method of claim 4, wherein the patterning device includes a plurality of patterns, and
wherein the obtaining of the first graph comprises changing a pitch of the plurality of patterns such that a slope of the first graph is increased.

9. The method of claim 8, wherein the lithography apparatus further includes an aperture configured to control a profile of the light beam, and
wherein the obtaining the first graph comprises controlling the aperture to change the optical path of the first diffraction light.

10. The method of claim 9, wherein the substrate further includes a second region that is not overlapped with the first region, and
wherein the method further comprises:
measuring a pattern shift amount on the second region, and
measuring a defocusing amount on the second region.

11. A method of using a lithography apparatus, the method comprising:
placing a patterning device and a substrate in the lithography apparatus;
irradiating, by the lithography apparatus, the substrate with a diffraction light; and
increasing a pattern shift amount on the substrate,
wherein the diffraction light includes a first diffraction light and a second diffraction light,
wherein the lithography apparatus comprises:
an illumination source configured to emit a light beam to be used as the diffraction light;
a substrate table supporting the substrate;
a supporting structure supporting the patterning device and optically connected to the illumination source; and
a projection part optically connected to the supporting structure and configured to irradiate the substrate with the diffraction light,
wherein the projection part includes an aperture that is configured to control a profile of the diffraction light,
wherein the illumination source includes a monopole source (MPS), and
wherein the increasing the pattern shift amount on the substrate comprises changing an optical path of the first diffraction light.

12. The method of claim 11, wherein the changing the optical path of the first diffraction light comprises changing the profile of the light beam by controlling the aperture.

13. The method of claim 11, wherein the increasing the pattern shift amount on the substrate further comprises changing an optical path of the second diffraction light.

14. The method of claim 13, wherein the patterning device includes a plurality of patterns, and
the changing the optical path of the second diffraction light comprises passing the light beam through a different pattern from among the plurality of patterns.

15. The method of claim 11, wherein the lithography apparatus further includes an illuminator configured to control an intensity distribution of the light beam,
wherein the illuminator includes a pupil unit configured to control uniformity and intensity of the light beam,
wherein the pupil unit includes a pupil plane, and
wherein the second diffraction light passes through a center of the pupil plane.

16. A method of using a lithography apparatus, the method comprising:
placing a patterning device and a substrate in the lithography apparatus;
irradiating, by the lithography apparatus, the substrate with a light beam;
causing a pattern shift on the substrate; and
increasing an amount of the pattern shift,
wherein the lithography apparatus includes:
an illumination source configured to emit the light beam;
an illuminator optically connected to the illumination source and configured to control the light beam;
a substrate table supporting the substrate;
a supporting structure supporting the patterning device; and
a projection part optically connected to the supporting structure and configured to irradiate the substrate with diffraction light, and
wherein the illumination source includes a monopole source (MPS).

17. The method of claim 16, wherein the light beam passes through the patterning device such as to form the diffraction light,
wherein the diffraction light includes a first diffraction light and a second diffraction light, and
wherein the increasing the amount of the pattern shift comprises increasing a difference in an optical path of the first diffraction light and an optical path of the second diffraction light.

18. The method of claim 16, wherein the increasing the amount of the pattern shift comprises increasing the amount of the pattern shift based on comparing a pattern with a pattern shift with a pattern without a pattern shift.

19. The method of claim 16, wherein the lithography apparatus is configured to execute an exposure process through one from among reflection-type and transmission-type exposure methods.

20. The method of claim 16, wherein the lithography apparatus further includes an aperture configured to control a profile of the light beam, and wherein the increasing the pattern shift comprises controlling at least one from among the aperture and the patterning device such that the pattern shift is increased.
